(19) United States
(12) Patent Application Publication
(10) Pub. No.: US 2008/0073779 A1
(43) Pub. Date: Mar. 27, 2008

(54) STACKED SEMICONDUCTOR PACKAGE AND METHOD OF MANUFACTURING THE SAME

(75) Inventor: Beung-Seuck SONG, Incheon (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/555,136

(22) Filed: Oct. 31, 2006

(30) Foreign Application Priority Data
Sep. 21, 2006 (KR) 2006-0091791

(51) Int. Cl. H01L 23/34

(52) U.S. Cl. 257/723

(57) ABSTRACT

Provided are highly reliable, high density stacked semiconductor packages including a plurality of semiconductor chips and a method of manufacturing the stacked semiconductor package. An embodiment of the stacked semiconductor package includes upper and lower semiconductor packages which are sequentially stacked. The upper and lower semiconductor packages include inner leads connected to semiconductor chips. The upper semiconductor package may further include outer leads connected to the inner leads of the upper semiconductor package and that extend outside an encapsulant to be electrically connected to the inner leads of the lower semiconductor package.

### CROSS-REFERENCE TO RELATED PATENT APPLICATION

This application claims the benefit of Korean Patent Application No. 10-2006-0091791, filed on Sep. 21, 2006, in the Korean Intellectual Property Office, the disclosure of which is incorporated by reference.

### BACKGROUND

1. Field of the Invention

The present invention relates to a semiconductor package, and more particularly, to a stacked semiconductor package and a method of manufacturing the same.

2. Description of the Related Art

Assembling technology for manufacturing semiconductor packages has been rapidly developing with the recent advancements in semiconductor device technology. In particular, the size of semiconductor packages has continued to be reduced to match the demand for compact and light products that contain such semiconductor packages. Typically, these semiconductor products require high capacity semiconductor packages to fulfill the technological requirements of the products. Thus, stacked semiconductor packages or a multi-chip semiconductor packages including a plurality of semiconductor chips are often used.

However, conventional stacked semiconductor packages are limited in general terms of thickness due to the necessary thickness of the encapsulant enclosing semiconductor chips in upper and lower semiconductor packages for protection. Also, the leads of each of the upper and lower semiconductor packages generally protrude underneath the encapsulant. Thus, the thickness of the general stacked semiconductor package may be further increased.

To address these problems, a method of forming leads of a semiconductor package to be parallel with an encapsulant has been suggested. However, these suggested stack structures of such semiconductor packages have reliability problems relating to the electrical connection between the leads of upper and lower semiconductor packages. For example, the contact area between leads may be small, and particles may be interposed between the leads during manufacturing or use, which degrades the electrical connections. Furthermore, in these suggested stack structures of the upper and lower semiconductor packages, the leads are generally formed using half etching. However, this leads to another problem because of the necessary etching depth required by half etching. In particular, as a result of the typical required etching depth, the stacked semiconductor package may be difficult to integrate in a compact multi-chip package that includes a plurality of semiconductor chips.

### SUMMARY

The present invention provides a highly reliable, high density stacked semiconductor package including a plurality of semiconductor chips, and further provides a method of manufacturing such highly reliable, high density stacked semiconductor package.

According to an embodiment of the present invention, a stacked semiconductor package may include sequentially stacked upper and lower semiconductor packages, each having at least one semiconductor chip, a plurality of inner leads connected to the chips, and an encapsulant covering the chips and inner leads. Additionally, the upper semiconductor package may include a plurality of outer leads connected to the inner leads that extend outside the encapsulant to be electrically connected to the inner leads of the lower semiconductor package.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a stacked semiconductor package according to an embodiment of the present invention;

FIG. 2 is a cross-sectional view of a stacked semiconductor package according to another embodiment of the present invention;

FIG. 3 is a cross-sectional view of a stacked semiconductor package according to another embodiment of the present invention;

FIG. 4 is a cross-sectional view of a stacked semiconductor package according to another embodiment of the present invention;

FIG. 5 is a cross-sectional view of a stacked semiconductor package according to another embodiment of the present invention;

FIG. 6 is a cross-sectional view of a stacked semiconductor package according to another embodiment of the present invention; and

FIGS. 7 through 10 are cross-sectional views illustrating a method of manufacturing a stacked semiconductor package according to an embodiment of the present invention.

### DETAILED DESCRIPTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity.

In the embodiments of the present invention, a stacked semiconductor package may refer to a structure in which at least one or more pairs of semiconductor packages are stacked and electrically connected to each other. Also, inner leads and outer leads are defined separately. The inner leads refer to leads or a portion of a lead frame including surfaces attached to and fixed to an encapsulant, and the outer leads refer to leads or a portion of a lead frame extending outside the molding resin. The inner and outer leads may refer to a structure body that is virtually divided into inner and outer leads physically connected to one another. Thus, in the embodiments of the present invention, a semiconductor package may include only inner leads or may include inner leads and outer leads.

FIG. 1 is a cross-sectional view of a stacked semiconductor package 100 according to an embodiment of the present invention. Referring to FIG. 1, the stacked semiconductor package 100 includes an upper semiconductor package 100b and a lower semiconductor package 100a, which are sequentially stacked. The lower and upper semiconductor packages 100a and 100b respectively include semiconductor chips 108 which are fixed and protected by the encapsulant 112. The semiconductor chips 108 may be attached to chip mounting pads 104 using adhesive members 106. The semiconductor chips 108 may include memory devices and/or logic devices. However, the present invention is not limited to these types of devices. Further, the semiconductor chips 108 of the lower and upper semiconductor packages 100a and 100b do not necessarily need to be similar to each other.

The encapsulant 112 protects the semiconductor chips 108 from the external environment and may include a molding resin having an epoxy molding compound (EMC). Although encapsulant 112 is discussed throughout these embodiments in a singular form, the encapsulant may encompass separate and distinct sections of resin material that may or may not be in contact with each other. Thus, the term encapsulant may include one or more portions of encapsulant or resin material. Alternatively, the encapsulant may be formed of a material other than resin. For example, the encapsulant may be formed using a ceramic material. The chip mounting pads 104 may also include notches 105 at their edges to help increase the bond strength between the chip mounting pads 104 and the encapsulant 112. Edge portions of the chip mounting pads 104 may further protrude toward the encapsulant 112 due to the notches 105 and may thus also be fixed by the encapsulant 112. However, the bottom surfaces of the chip mounting pads 104 may be exposed from the encapsulant 112. In a modification of the present embodiment, holes (not shown) may be formed at the chip mounting pads 104 instead of the notches 105 or may be formed together with the notches 105 at the chip mounting pads 104.

A plurality of inner leads 102 may respectively be electrically connected to the semiconductor chips 108 through wires 110 and may further be encompassed or encapsulated by the encapsulant 112. The inner leads 102 may include upper surfaces to which the wires 10 are connected and bottom surfaces opposite the upper surfaces. The upper surfaces of the inner leads 102 may be attached to and fixed to the encapsulant 112. At least portions of the bottom surfaces of the inner leads 102 may be exposed from the encapsulant 112. In addition, sides of the inner leads 102 may be exposed from the encapsulant 112. The exposed portions of the inner leads 102 may be used as portions connected to another semiconductor package in a stack structure or operate as external terminals. The lower and upper semiconductor packages 100a and 100b may be referred to as exposed lead packages (ELPs) due to the structures of inner leads 102 and/or the chip mounting pads 104. However, the scope of the present invention is not limited to this name.

The inner leads 102 may also include notches 103 to increase the bond strength between the inner leads 102 and the encapsulant 112. As shown in FIG. 1, edge portions of the inner leads 102 may protrude inward over a portion of the encapsulant 112 due to the notches 103, which may increase the bond strength between the inner leads 102 and the encapsulant 112. In a modification of the present embodiment, the inner leads 102 may include holes (not shown) instead of the notches 103 or may include the holes along with the notches 103 to further increase this bond strength with the encapsulant 1112. The notches 103 or the holes may be formed using a half etching method and filled with the encapsulant 112.

In another modification of the present embodiment, nonconductive intermediate members 120, as shown in FIG. 8, may be interposed between the upper surfaces of the inner leads 102 and the encapsulant 112. The intermediate members 120 may extend across at least portions of the inner leads 102 to increase the bond strength between the encapsulant 112 and the inner leads 102. For example, the intermediate members 120 may extend across the upper surfaces of the inner leads 102 and have bar shapes. In this case, the inner leads 102 may not include the notches 103.

In yet another modification of the present embodiment, the chip mounting pads 104 may be omitted, and thus the semiconductor chips 108 may be disposed directly on the inner leads 102 so as to be electrically connected to the inner leads 102. This structure may be called a lead on chip (LOC) structure.

The upper semiconductor package 100b may further include a plurality of outer leads 114b. The outer leads 114b may be connected to the inner leads 102 and extend outside the area that the encapsulant 112 encompasses. For example, the outer leads 114b may be physically connected to the inner leads 102 and formed in a downward manner, i.e., toward the lower semiconductor package 100a. The outer leads 114b may further be electrically connected to the inner leads 102 of the lower semiconductor package 100a; thus resulting in the inner leads 102 of the lower semiconductor package 100a being electrically connected to the inner leads 102 of the upper semiconductor package 100b.

For example, edge portions of the outer leads 114b may be soldered to the side walls of the inner leads 102 of the lower semiconductor package 100a. In the present embodiment, the outer leads 114b may also be bent downward from the inner leads 102 of the upper semiconductor package 100a. Thus, the inner leads 102 of the upper semiconductor package 100b may be placed on the encapsulant 112 of the lower semiconductor package 100a. In other words, the outer leads 114b may not be interposed between the lower and upper semiconductor packages 100a and 100b but may be disposed outside the encapsulant 112 of both the lower and upper semiconductor packages 100a and 100b so as to reduce the height and volume of the stacked semiconductor package 100.

Furthermore, since the outer leads 114b may be bent using a forming method rather than a half etching method, the necessary dimensions of the outer leads 114b and the entire stacked semiconductor package 100 may be reduced. Further, a plurality of other semiconductor chips (not shown) may be stacked on the semiconductor chips 108 of the lower and upper semiconductor packages 100a and 100b. As a result, the lower and upper semiconductor packages 100a and 100b may be easily modified into multi-chip packages.

When the stacked semiconductor package 100 is mounted on a circuit board (not shown), the edge portions of the outer leads 114b and the inner leads 102 of the lower semiconductor package 100a may contact wiring lines of the circuit board. As a result, the contact area between the stacked semiconductor package 100 and the circuit board (not shown) may be increased, which in turn may improve the reliability of the electrical connection between the stacked semiconductor package 100 and the circuit board (not shown).

Although the above embodiment has been described with reference to only an upper and lower semiconductor package 100a and 100b, the stacked semiconductor package 100 may include a plurality of other semiconductor packages (not shown) that are further stacked on the upper and lower semiconductor packages 110a and 100b, and electrically connected to them.

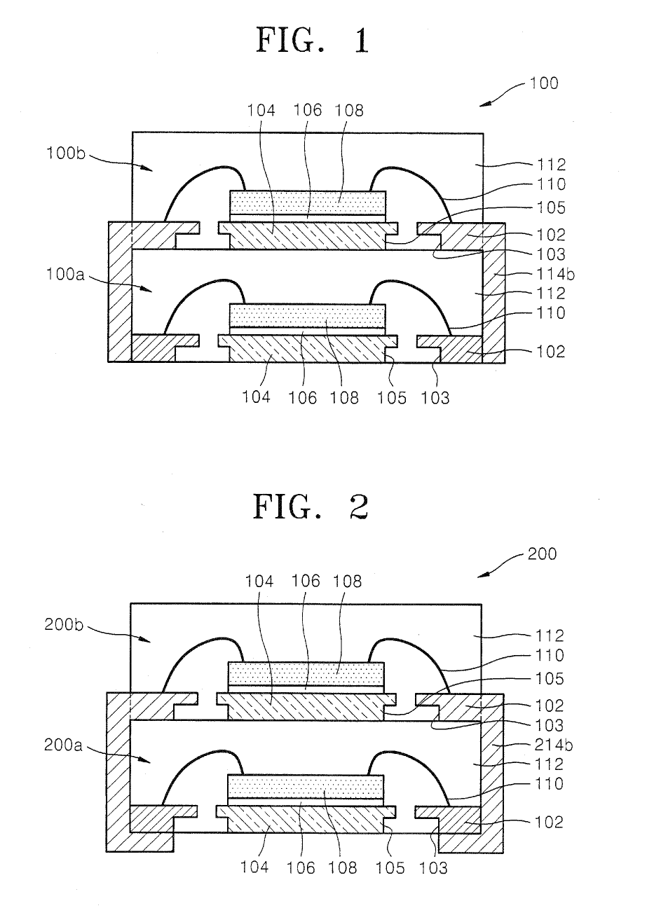

FIG. 2 is a cross-sectional view of a stacked semiconductor package 200 according to another embodiment of the present invention. The stacked semiconductor package 200 is similar to the stacked semiconductor package 100 shown in FIG. 1 except for the shapes and connection method of outer leads. Thus, repeated descriptions of similar elements present in both embodiments will be omitted so that the differences between the two embodiments can be more clearly described.

Referring to FIG. 2, the stacked semiconductor package 200 includes an upper semiconductor package 200b and a lower semiconductor package 200a which are sequentially stacked. The lower and upper semiconductor packages 200a and 200b respectively correspond to the lower and upper semiconductor packages 100a and 100b shown in FIG. 1. However, outer leads 214b of the upper semiconductor package 200b may additionally be electrically connected to bottom portions of the inner leads 102 of the lower semiconductor package 200a, rather than solely connected to the edge portions of the inner leads 102 of the lower semiconductor package 100a as illustrated in FIG. 1. For example, edge portions of the outer leads 214b may be electrically connected to the bottom portions of the inner leads 102 of the lower semiconductor package 200a. In this case, the outer leads 214b may be bent two times during formation.

Thus, the edge portions of the outer leads 214b protrude underneath encapsulant 112 of the lower semiconductor package 200a. This shape of the outer leads 214b may be used to further improve the reliability of an electrical connection between the stacked semiconductor package 200 and a circuit board (not shown). In this case, wiring lines of the circuit board may be recessed to keep the overall size and volume of the circuit board small.

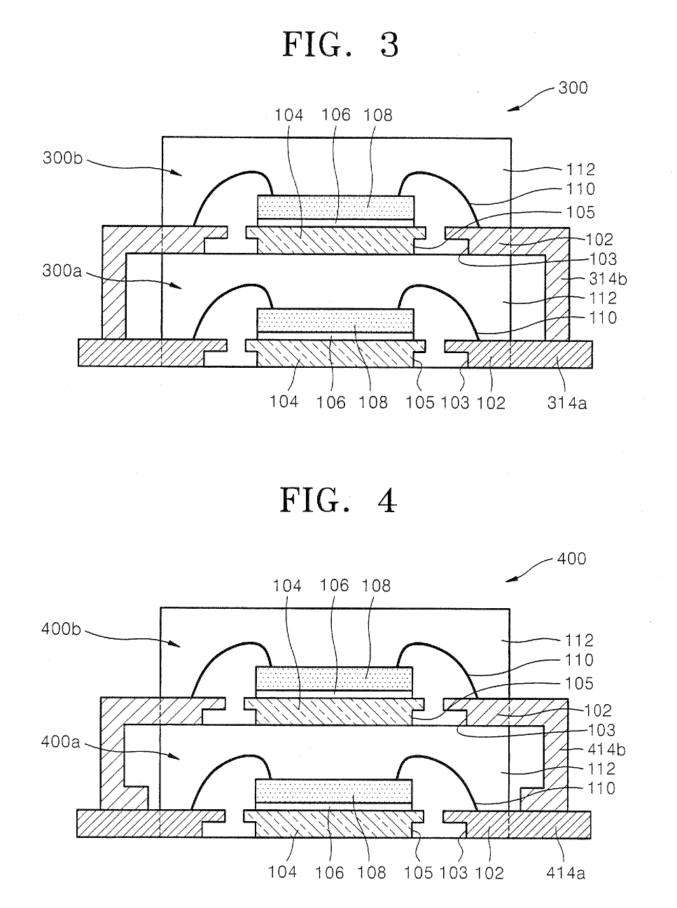

FIG. 3 is a cross-sectional view of a stacked semiconductor package 300 according to another embodiment of the present invention. The stacked semiconductor package 300 is similar to the stacked semiconductor package 100 shown in FIG. 1 except for the shape and connection method of the outer leads. Thus, repeated descriptions of similar elements present in both embodiments illustrated in FIGS. 1 and 3 will be omitted so that the differences between the embodiments can be more clearly described.

Referring to FIG. 3, the stacked semiconductor package 300 includes an upper semiconductor package 300b and a lower semiconductor package 300a, which are sequentially stacked. The lower and upper semiconductor packages 300a and 300b may respectively correspond to the lower and upper semiconductor packages 110a and 110b shown in FIG. 1. However, outer leads 314b of the upper semiconductor package 300b have different shapes from the outer leads 114b shown in FIG. 1. Also, the lower semiconductor package 300a further includes a plurality of outer leads 314a.

In more detail, the outer leads 314a of the lower semiconductor package 300a are connected to inner leads 102 of the lower semiconductor package 300a and extend outside the encapsulant 112. For example, the outer leads 314a may extend from the inner leads 102 of the lower semiconductor package 300a. The outer leads 314a may further be physically connected to the inner leads 102 of the lower semiconductor package 300a.

The outer leads 314b may be formed in a downward manner, i.e., toward the lower semiconductor package 300a, and edge portions of the outer leads 314b may be electrically connected to the outer leads 314a. For example, the edge portions of the outer leads 314b may be disposed perpendicular to a direction along which the outer leads 314a extend and soldered to the outer leads 314a. For example, the outer leads 314b may linearly extend from the inner leads 102 of the upper semiconductor package 300b and then be bent downward.

The stacked semiconductor package 300 may have similar advantages as the stacked semiconductor package 100 shown in FIG. 1. However, when the stacked semiconductor package 300 is mounted on a circuit board, the stacked semiconductor package 300 may have a lower contact resistance and a higher connection reliability than the stacked semiconductor package 100 shown in FIG. 1. In other words, in the stacked semiconductor package 300, contact areas of the outer leads 314a and the inner leads 102 of the lower semiconductor package 300a that electrically contact the circuit board may be very wide and hence improve the connection reliability.

FIG. 4 is a cross-sectional view of a stacked semiconductor package 400 according to another embodiment of the present invention. The stacked semiconductor package 400 is similar to the stacked semiconductor package 300 shown in FIG. 3 except for the shapes and connection method of the outer leads. Thus, repeated descriptions of similar elements present in both embodiments will be omitted so that the differences between the two embodiments can be more clearly described.

Referring to FIG. 4, the stacked semiconductor package 400 includes an upper semiconductor package 400b and a lower semiconductor package 400a, which are sequentially stacked. The lower and upper semiconductor packages 400a and 400b may respectively correspond to the lower and upper semiconductor packages 300a and 300b shown in FIG. 3. However, outer leads 414b of the upper semiconductor package 400b have a different shape from the outer leads 314b shown in FIG. 3. The outer leads 414a of the lower semiconductor package 400a may still have a similar shape as the outer leads 314a shown in FIG. 3.

In particular, while the outer leads 414a of the lower semiconductor package 400a may still extend from the inner leads 102 of the lower semiconductor package 400a, the edge portions of the outer leads 414b may be formed to be parallel to the direction along which the outer leads 414a extend. For example, the outer leads 414b may linearly extend from inner leads 102 of the upper semiconductor package 400b, be bent downward, and be bent once more to be parallel with the outer leads 414a. In FIG. 4, it is shown that the edge portions of the outer leads 414b are bent toward the lower semiconductor package 400a; however, these edge portions of the outer leads 414b may also be bent away from the lower semiconductor package 400a. Also, it will be obvious that the outer leads 414b do not need to be formed at a right angle as shown in FIG. 4. As with the previous embodiments, the outer leads 414b may also be soldered to, and hence electrically connected to, the outer leads 414a.

In the stacked semiconductor package 400, the contact areas between the outer leads 414a and 414b may be increased as compared to the stacked semiconductor package 300 shown in FIG. 3. Thus, the stacked semiconductor package 400 may have the same advantages as the stacked semiconductor package 300 shown in FIG. 3, but with a higher electrical connection reliability.

FIG. 5 is a cross-sectional view of a stacked semiconductor package 500 according to another embodiment of the present invention. The stacked semiconductor package 500 is similar to the stacked semiconductor packages 300 except for the shapes and connection method of the outer leads. Thus, repeated descriptions of similar elements present in both embodiments will be omitted, so that the differences between the two embodiments can be more clearly described.

Referring to FIG. 5, the stacked semiconductor package 500 includes an upper semiconductor package 500b and a lower semiconductor package 500a, which are sequentially stacked. The lower and upper semiconductor packages 500a and 500b may respectively correspond to the lower and upper semiconductor packages 300a and 300b shown in FIG. 3. However, the outer leads 514a of the lower semiconductor package 500a have a different shape from the outer leads 314a shown in FIG. 3. The outer leads 514b of the upper semiconductor package 500b may correspond to the outer leads 314b shown in FIG. 3.

In particular, while the outer leads 514b of the upper semiconductor package 500b may still extend from the inner leads 102 of the upper semiconductor package 500b and be bent downward, the edge portions of the outer leads 514a may be formed so as to be parallel with edge portions of the outer leads 514b. For example, the outer leads 514a may linearly extend from inner leads 102 of the lower semiconductor package 500a and then be bent upward. The edge portions of the outer leads 514a and 514b may be parallel with a sidewall of an encapsulant 112. However, the scope of the present invention is not limited to this direction. Additionally, as with the previous embodiments, the outer leads 414b may also be soldered to, and hence electrically connected to, the outer leads 414a.

In the stacked semiconductor package 500, the contact areas between the outer leads 514a and 514b may be increased as compared to those of the semiconductor package 300. Thus, a higher electrical connection reliability may be obtained.

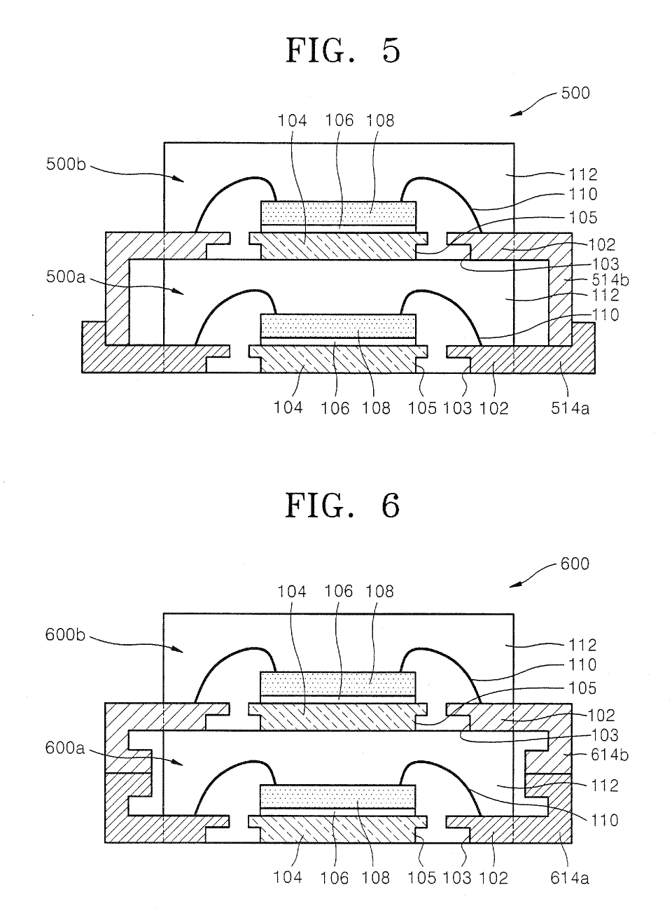

FIG. 6 is a cross-sectional view of a stacked semiconductor package 600 according to another embodiment of the present invention. The stacked semiconductor package 600 is similar to the stacked semiconductor package 400 shown in FIG. 4 except for the shapes and connection method of the outer leads. Thus, repeated descriptions of similar elements present in both embodiments will be omitted, so that the differences between the two embodiments can be more clearly described.

Referring to FIG. 6, the stacked semiconductor package 600 includes an upper semiconductor package 600b and a lower semiconductor package 600a, which are sequentially stacked. The lower and upper semiconductor packages 600a and 600b may respectively correspond to the lower and upper semiconductor packages 400a and 400b shown in FIG. 4. However, the outer leads 614a and 614b may have a different shape and connection scheme from the outer leads 414a and 414b shown in FIG. 4.

In particular, the edge portions of both the outer leads 614a and the outer leads 614b may be bent and electrically connected together. For example, the outer leads 614b may have a similar shape to the outer leads 414b shown in FIG. 4 but not extend in the downward direction as far as the outer leads 414b shown in FIG. 4. The outer leads 614a linearly extend from inner leads 102 of the lower semiconductor package 600a, are bent upward, and are then bent parallel with the edge portions of the outer leads 614b. Although the edge portions of the outer leads 614a and 614b are shown in FIG. 6 as being bent toward the semiconductor packages, they may be bent away from the semiconductor packages in other embodiments. Again, the edge portions of the outer leads 614a and 614b opposite each other may be soldered together, and hence, electrically connected.

In FIG. 6, the outer leads 614a and 614b are shown as being bent two times at a right angle so that the edge portions of the outer leads 614a and 614 are perpendicular to the sidewall of the encapsulant 112. However, the scope of the present invention is not limited to such a right angle; rather the edge portions of the outer leads 614a and 614b may be modified into various forms within a range in which the edge portions of the outer leads 614a and 614 are parallel.

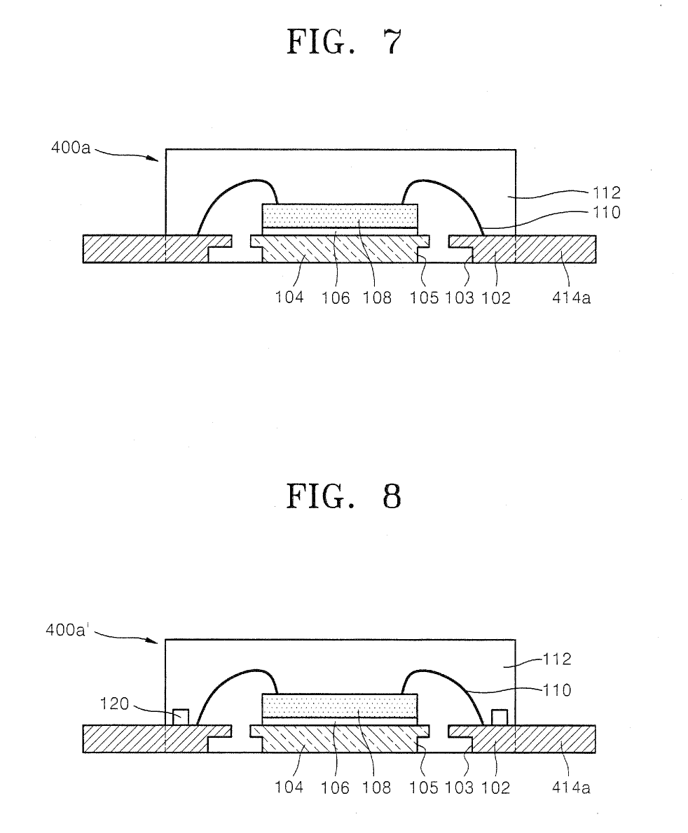

FIGS. 7 through 10 are cross-sectional views illustrating a method of manufacturing a stacked semiconductor package according to an embodiment of the present invention.

Hereinafter, a method of manufacturing the stacked semiconductor package 400 shown in FIG. 4 will be exemplarily described. However, such a method may be easily applied to the other embodiments described with reference to FIGS. 1 through 6.

Referring to FIG. 7, the lower semiconductor package 400a is provided. For example, the semiconductor chips 108 are mounted on the chip mounting pads 104, the semiconductor chips 108 are connected to the inner leads 102 using the wires 110, and the encapsulant 112 may be formed to encapsulate and fix the semiconductor chips 108 and the inner leads 102. The inner leads 102 and the outer leads 414a may be virtually defined as portions of the same leads or lead frames by the encapsulant 112.

Referring to FIG. 8, a lower semiconductor package 400a′ is a modification example of the lower semiconductor package 400a shown in FIG. 7. The lower semiconductor package 400a′ may further include the nonconductive intermediate members 120 between the upper surfaces of the inner leads 102 and the encapsulant 112. As described above, the intermediate members 120 may increase the bond strength between the inner leads 102 and the encapsulant 112. For example, the intermediate members 120 may be disposed across the inner leads 102 to fix the inner leads 102. The intermediate members 120 may be used along with or instead of the notches 103. As described above, such a modification example may be applied to the lower and upper semiconductor packages of the embodiments described with reference to FIGS. 1 through 6.

The method described with reference to FIGS. 7 and 8 may be applied to the other embodiments. For example, in the embodiments described with reference to FIGS. 1 and 2, the lower semiconductor packages 100a and 200a may be manufactured by trimming or cutting the outer leads 414a of the lower semiconductor package 400 as described above. In the embodiments described with reference to FIGS. 5 and 6, the lower semiconductor packages 500a and 600a may be easily formed by forming the outer leads 414a of the lower semiconductor package 400a in a corresponding form.

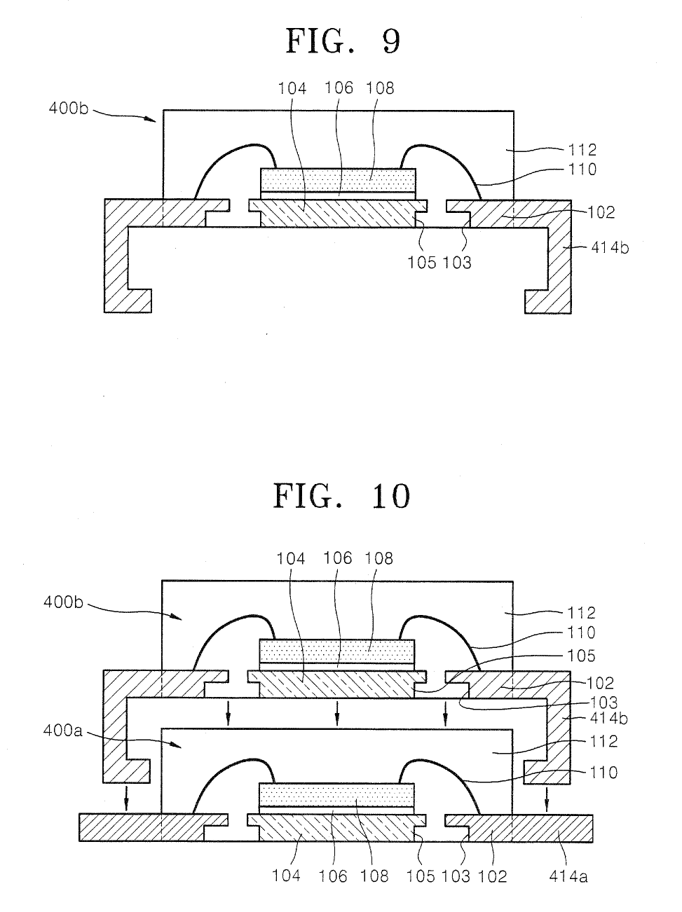

Referring to FIG. 9, the upper semiconductor package 400b is provided. A method of forming the upper semiconductor package 400b is similar to the method of forming the lower semiconductor package 400a illustrated in FIG. 7. For example, the outer leads 414a of the lower semiconductor package 400a shown in FIG. 7 may be bent downward two times to form the upper semiconductor package 400b.

The upper semiconductor packages 100b, 200b, 300b, 500b, and 600b shown in FIGS. 1, 2, 3, 5, and 6 may be easily formed by modifying the above-described forming step.

Referring to FIG. 10, the upper semiconductor package 400b is stacked on the lower semiconductor package 400a. Next, the outer leads 414a and 414b may be electrically connected to each other to form the stacked semiconductor package 400 as shown in FIG. 4. The electrical connection between the outer leads 414a and 414b may be facilitated using solder bonding. For example, the edge portions of the outer leads 414b may be soldered to the outer leads 414a.

These stack and connection steps may easily be applied to the stacked semiconductor packages 100, 200, 300, 500, and 600 shown in FIGS. 1, 2, 3, 5, and 6.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a lower semiconductor package including:
a semiconductor chip,
a plurality of inner leads electrically connected to the semiconductor chip, and
an encapsulant covering the semiconductor chip and the inner leads; and
an upper semiconductor package sequentially stacked on the lower semiconductor package, the upper semiconductor package including:
a semiconductor chip,
a plurality of inner leads electrically connected to the semiconductor chip,
an encapsulant covering the semiconductor chip and the inner leads, and
a plurality of outer leads extending outside the encapsulant from the inner leads of the upper semiconductor package and electrically connected to the inner leads of the lower semiconductor package.

2. The semiconductor package of claim 1, wherein at least a portion of a bottom surface of each of the plurality of inner leads of the lower semiconductor package is exposed from the encapsulant.

3. The semiconductor package of claim 1, wherein bottom surfaces of the inner leads of the upper semiconductor package are placed on an upper surface of the encapsulant of the lower semiconductor package.

4. The semiconductor package of claim 1, wherein the outer leads of the upper semiconductor package are bent downward to electrically connect to the inner leads of the lower semiconductor package.

5. The semiconductor package of claim 4, wherein edge portions of the outer leads of the upper semiconductor package are electrically connected to sidewalls of the inner leads of the lower semiconductor package.

6. The semiconductor package of claim 4, wherein edge portions of the outer leads of the upper semiconductor package are electrically connected to the bottom surfaces of the inner leads of the lower semiconductor package.

7. The semiconductor package of claim 4, wherein edge portions of the outer leads of the upper semiconductor package are soldered to the inner leads of the lower semiconductor package.

8. The semiconductor package of claim 1, wherein the inner leads of the upper and lower semiconductor packages include notches or holes.

9. The semiconductor package of claim 8, where in the notches or holes are filled with a portion of the encapsulant to improve a bond strength between the inner leads and the encapsulant.

10. The semiconductor package of claim 1, wherein the upper and lower semiconductor packages further comprise nonconductive intermediate members interposed between the inner leads and the encapsulant.

11. The semiconductor package of claim 1, wherein the upper and lower semiconductor packages further comprise chip mounting pads on which the semiconductor chips are mounted, and wherein bottom surfaces of the chip mounting pads are exposed from the encapsulant.

12. A stacked semiconductor package comprising:
upper and lower semiconductor packages sequentially stacked,
wherein each of the upper and lower semiconductor packages comprises:
a semiconductor chip;
a plurality of inner leads comprising upper surfaces and bottom surfaces, the inner leads electrically connected to the semiconductor chip;
an encapsulant covering the semiconductor chip and the inner leads; and
a plurality of outer leads connected to the inner leads and extending outside the encapsulant, wherein the upper surfaces of the upper and lower semiconductor packages are fixed to the encapsulant, portions of the bottom surfaces are exposed from the encapsulant, and the outer leads of the upper semiconductor package are formed toward the lower semiconductor package to be electrically connected to the outer leads of the lower semiconductor package.

13. The stacked semiconductor package of claim 12, wherein the bottom surfaces of the inner leads of the upper semiconductor package are placed on an upper surface of the encapsulant of the lower semiconductor package.

14. The stacked semiconductor package of claim 12, wherein the outer leads of the upper semiconductor package are bent downward to electrically connect with the outer leads of the lower semiconductor package.

15. The stacked semiconductor package of claim 14, wherein edge portions of the outer leads of the upper semiconductor package are electrically connected to the outer leads of the lower semiconductor package.

16. The stacked semiconductor package of claim 15, wherein the edge portions of the outer leads of the upper semiconductor package are soldered to and electrically connected to the outer leads of the lower semiconductor package.

17. The stacked semiconductor package of claim 12, wherein the outer leads of the lower semiconductor package linearly extend from sidewalls of the inner leads of the lower semiconductor package.

18. The stacked semiconductor package of claim 17, wherein the edge portions of the outer leads of the upper semiconductor package are formed to be parallel with a direction along which the outer leads of the lower semiconductor package extend.

19. The stacked semiconductor package of claim 17, wherein the edge portions of the outer leads of the upper semiconductor package are perpendicular to a direction along which the outer leads of the lower semiconductor package extend.

20. The stacked semiconductor package of claim 15, wherein the outer leads of the lower semiconductor package are formed toward the upper semiconductor package, and the edge portions of the outer leads of the upper semiconductor package are electrically connected to edge portions of the outer leads of the lower semiconductor package.

21. The stacked semiconductor package of claim 20, wherein the edge portions of the outer leads of the upper and lower semiconductor packages are formed to be perpendicular to a sidewall of the encapsulant.

22. The stacked semiconductor package of claim 20, wherein the edge portions of the outer leads of the upper and lower semiconductor packages are formed to be parallel to a sidewall of the encapsulant.

23. The stacked semiconductor package of claim 12, wherein the inner leads of the upper and lower semiconductor packages include notches or holes that are filled with a portion of the encapsulant to improve a bond strength between the inner leads and the encapsulant.

24. The stacked semiconductor package of claim 12, wherein the upper and lower semiconductor packages further comprise nonconductive intermediate members interposed between the inner leads and the encapsulant.

25. The stacked semiconductor package of claim 12, wherein the outer leads of the upper semiconductor package are physically connected to the inner leads of the upper semiconductor package, and the inner leads of the lower semiconductor package are physically connected to the outer leads of the lower semiconductor package.

26. A method of manufacturing a semiconductor package, the method comprising:
providing a lower semiconductor package including a semiconductor chip, a plurality of inner leads electrically connected to the semiconductor chip, and an encapsulant covering the semiconductor chip and inner leads;
providing an upper semiconductor package including a semiconductor chip, a plurality of inner leads electrically connected to the semiconductor chip, an encapsulant covering the semiconductor chip and inner leads, and a plurality of outer leads extending from the inner leads;
bending the outer leads of the upper semiconductor package in a downward manner;
stacking the upper semiconductor package on the lower semiconductor package; and
electrically connecting the outer leads of the upper semiconductor package to the inner leads of the lower semiconductor package.

27. The method of claim 26, wherein stacking the upper semiconductor package on the lower semiconductor package includes disposing bottom surfaces of the inner leads of the upper semiconductor package on an upper surface of the encapsulant of the lower semiconductor package.

28. The method of claim 26, wherein electrically connecting the outer leads of the upper semiconductor package to the inner leads of the lower semiconductor package includes solder bonding the outer leads of the upper semiconductor package to the inner leads of the lower semiconductor package.

29. The method of claim 28, wherein the solder bonding is performed with respect to edge portions of the outer leads of the upper semiconductor package and sidewalls or bottom surfaces of the inner leads of the lower semiconductor package.

30. The method of claim 26, wherein the lower semiconductor package further comprises outer leads connected to the inner leads and extending outside the encapsulant, and wherein electrically connecting the outer leads of the upper semiconductor package to the inner leads of the lower semiconductor package includes electrically connecting the outer leads of the upper semiconductor package to the outer leads of the lower semiconductor package.

31. The method of claim 30, wherein electrically connecting the outer leads of the upper semiconductor package to the outer leads of the lower semiconductor package includes solder bonding the outer leads of the upper semiconductor package to the outer leads of the lower semiconductor package.

32. The method of claim 30, wherein the solder bonding is performed with respect to edge portions of the outer leads of the upper semiconductor package and edge portions of the outer leads of the lower semiconductor package.
